(19) United States
(12) Patent Application Publication
(10) Pub. No.: US 2026/0100335 A1
(43) Pub. Date: Apr. 9, 2026

(54) PLASMA PROCESSING DEVICE INCLUDING BAFFLE FOR PLASMA CONFINING

(71) Applicant: VM Inc., Icheon-si (KR)

(72) Inventors: Sang Woo Lee, Suwon-si (KR); Woo Hyung Choi, Seongnam-si (KR)

(21) Appl. No.: 18/894,722

(22) Filed: Sep. 24, 2024

(30) Foreign Application Priority Data
Jul. 31, 2024 (KR) 10-2024-0101720

(51) Int. Cl. H01J 37/32

(52) U.S. Cl. CPC H01J 37/3244; H01J 37/32715; H01J 2237/20235; H01J 2237/20278

(57) ABSTRACT

A plasma processing device is proposed. The plasma processing device includes an electrostatic chuck configured to support a substrate inside a chamber, and a baffle including a body section having a cylindrical shape and a wing section having a ring shape along an edge of the body section, wherein the wing section includes a first set of slits configured to discharge at least a part of gas provided for the substrate.

### STATEMENT REGARDING GOVERNMENT SPONSORED RESEARCH OR DEVELOPMENT

The present disclosure was developed in the task of a project to develop next-generation 300 mm high aspect ratio process oxide film dry etching equipment (Project identification number: 1415182778, Project number: P0021943, Ministry name: Ministry of Trade, Industry and Energy, Project management organization name: Korea Institute for Advancement of Technology, Research project name: World Class Plus Project Support, Project implementation organization name: APTC Co., Ltd. (VM Inc.), Research period: 2022 Jun. 1˜2025 Dec. 31.)

### CROSS REFERENCE TO RELATED APPLICATIONS

This application claims priority under 35 U.S.C. § 119 to Korean Patent Application No. 10-2024-0101720 filed on Jul. 31, 2024, in the Korean Intellectual Property Office, the disclosures of which are incorporated by reference herein in their entireties. Meanwhile, in all the aspects of the inventive concept, there is no property interest in the government of the Republic of Korea.

### BACKGROUND

### 1. Technical Field

The present disclosure relates to a plasma processing device and, more particularly, to a plasma processing device including a baffle for plasma confining.

### 2. Description of the Related Art

A substrate processing apparatus for a semiconductor process is supplied with plasma gas into a processing chamber to process a substrate. Herein, a baffle in the processing chamber is a jig provided to control a flow of plasma gas.

Meanwhile, in general, plasma gas provided above the substrate is unevenly distributed above the substrate. To maximize an area of the substrate to be used in the semiconductor process, it is important to distribute plasma gas evenly above the substrate. However, in general, a thickness of a plasma gas layer distributed above a center region of the substrate is thicker than a thickness of a plasma gas layer distributed above an edge region of the substrate, which is a problem. Therefore, a plasma processing technique is required to distribute plasma evenly.

The present disclosure is derived from the research performed as part of the development of a next-generation 300 mm high aspect ratio process oxide layer dry etching device (Serial number of project: 1415182778, Project number: P0021943, Name of ministry: Ministry of Trade, Industry and Energy, Name of project managing organization: Korea Institute for Advancement of Technology, Title of research project: World-class plus project, Name of project executing organization: VM Inc., and Research period: 2022 Jun. 1˜2025 Dec. 31).

Meanwhile, as the project provider, the Korean government has no profit of assets in any aspect of the present disclosure.

### SUMMARY

An objective of the present disclosure is to provide a plasma processing device including a baffle for plasma confining.

According to an embodiment, there is provided a plasma processing device including: an electrostatic chuck configured to support a substrate inside a chamber; and a baffle including a body section having a cylindrical shape and a wing section having a ring shape along an edge of the body section, wherein the wing section may include a first set of slits configured to discharge at least a part of gas provided for the substrate.

Herein, the body section may include a second set of slits configured to discharge at least a part of gas provided for the substrate.

Herein, the plasma processing device may include: a baffle gear connected to both the electrostatic chuck and the baffle and, while being rotated at a first angle, configured to move the electrostatic chuck to a first height and to move the baffle to a second height, wherein the second height may be higher than the first height.

Herein, depending on the raising by the baffle gear, the electrostatic chuck may be raised to a first point, and the baffle may be raised to a second point, and the second point may be higher than the first point.

Herein, the plasma processing device may further include: a first ball screw supporting the electrostatic chuck; and a second ball screw supporting the baffle gear.

Herein, the plasma processing device may further include: a first bellows configured to contain the first ball screw; and a second bellows configured to contain the second ball screw, wherein a vacuum region may be provided between the first bellows and the second bellows.

Herein, the plasma processing device may further include: a pulley connected to the second ball screw; and a motor connected to the pulley by a belt, wherein to minimize a strain on the motor due to the vacuum region, the motor may be provided outside the chamber to provide power to the second ball screw by the belt.

Herein, the body section may include a second set of slits configured to discharge at least a part of gas provided for the substrate, and a position of the second set of slits may be set between a height of a lower end of the electrostatic chuck at the first point and a height of the second point.

Herein, the first set of slits may be arranged in a predetermined radius from a center portion of the baffle.

Herein, the first set of slits may include a first sub-set of slits and a second sub-set of slits, wherein the first sub-set of slits may be disposed in a first radius from the center portion of the baffle, and the second sub-set of slits may be arranged in a second radius larger than the first radius from the center portion of the baffle.

According to an embodiment of the present disclosure, the plasma processing device including the baffle for plasma confining may be provided.

### BRIEF DESCRIPTION OF THE DRAWINGS

FIG. 1 is a view illustrating a plasma processing device according to an embodiment of the present disclosure.

FIG. 2 is a view illustrating raising of an electrostatic chuck and raising of a baffle by a baffle gear of the present disclosure.

FIG. 3 is a view illustrating the electrostatic chuck and the baffle at one point according to the raising.

FIGS. 4, 5 and 6 are views illustrating the baffle according to an embodiment of the present disclosure.

FIG. 7 is a view illustrating the baffle according to another embodiment of the present disclosure.

FIGS. 8, 9 and 10 are views illustrating the baffle according to further embodiments of the present disclosure.

### DETAILED DESCRIPTION OF EXEMPLARY EMBODIMENTS

The embodiments disclosed in the specification are only provided for allowing one of ordinary skill in the art to which the present disclosure belongs to more clearly comprehend the scope and spirit of the present disclosure. The present disclosure is intended to cover not only the exemplary embodiment, but also various alternatives, modifications, equivalents, and other embodiments that may be included within the spirit and scope of the present disclosure.

Terms used in the specification are selected from general terms that are currently widely used, in consideration of their function in the present disclosure, which may be varied according to the intention of one of ordinary skill in the art to which the present disclosure belongs, precedent, the advent of new technologies, etc. However, on the other hand, when a specific term is used with an arbitrary definition, the meaning of the term will be described separately. Therefore, the terms used in the specification should not be interpreted as mere term names, but should be interpreted based on the practical meanings of the terms and the contents of this specification, not simple names of the terms.

Accompanying drawings of the specification are provided to illustrate the present disclosure, and the shapes in the drawings may be exaggerated for the convenience of understanding the present disclosure, so due to this, the present disclosure should not be interpreted narrowly.

In the specification, detailed descriptions of known configurations or functions which are deemed to make the gist of the present disclosure obscure will be omitted.

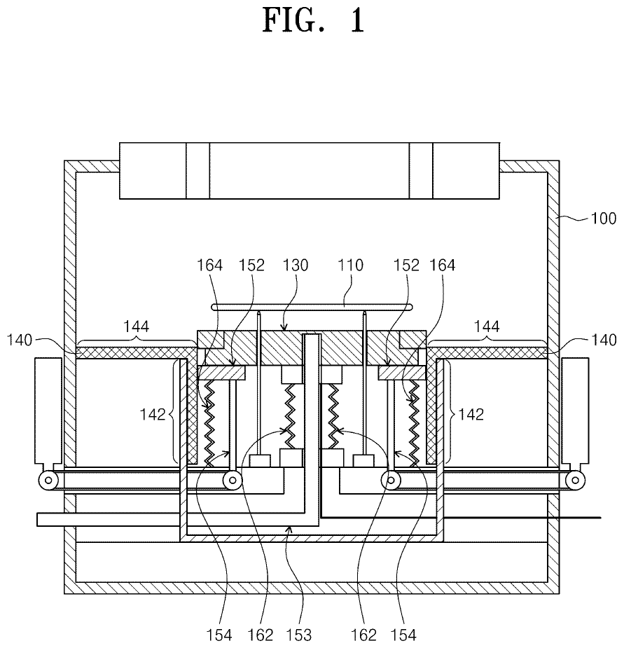

FIG. 1 is a view illustrating a plasma processing device according to an embodiment of the present disclosure.

Referring to FIG. 1, the plasma processing device according to an embodiment may include an electrostatic chuck (ESC) 130 and a baffle 140, a baffle gear 152, a first ball screw 153, a second ball screw 154, a first bellows 162, and a second bellows 164. The plasma processing device is not limited thereto and may include components more or less than the above components.

The plasma processing device is a device processing a substrate 110 used in a semiconductor process. For example, the plasma processing device may be a processing chamber, but is not limited thereto. The plasma processing device may process the substrate 110 by using plasma gas. The plasma processing device may include the substrate 110, the electrostatic chuck 130 housing the substrate 110, a component that may control movement of the electrostatic chuck 130, and a component for processing the substrate 110.

A partial region inside the plasma processing device may be a vacuum. For example, a space where the substrate 110 is positioned in the plasma processing device may be a vacuum to perform plasma processing. In order to maintain a partial region in a vacuum, the plasma processing device may include devices for maintaining a vacuum.

Furthermore, a partial region in the plasma processing device may be a non-vacuum. For example, a region where a component controlling movement of the electrostatic chuck 130 is provided may be a non-vacuum. At this point, the vacuum region and the non-vacuum region may be divided from each other to prevent a change in the state of each region.

The electrostatic chuck 130 may be configured to support the substrate 110. For example, the electrostatic chuck 130 may adhere the substrate 110 to support the substrate 110. The electrostatic chuck 130 may be raised in a chamber 100 to reduce a separation distance between the electrostatic chuck 130 and the substrate 110. Specifically, the electrostatic chuck 130 may move toward the substrate 110 by using the first ball screw 153 and the first bellows 162 that are connected to the electrostatic chuck 130. At this point, to efficiently perform the plasma processing of the substrate 110, the first ball screw 153 may be connected to the electrostatic chuck 130 to transmit electrical energy to the electrostatic chuck 130.

When a distance between the electrostatic chuck 130 and the substrate 110 is reduced to be less than or equal to a predetermined distance as the electrostatic chuck 130 is raised, the substrate 110 may be adhered to the electrostatic chuck 130 on the basis of static generated in the electrostatic chuck 130. Accordingly, the electrostatic chuck 130 may support and/or fix the substrate 110 horizontally.

The baffle 140 may be contained in the plasma processing device. The baffle 140 may divide the internal space of the plasma processing device into a plurality of regions. Specifically, the baffle 140 may be disposed to divide the internal space of the electrostatic chuck 130 into an upper space and a lower space.

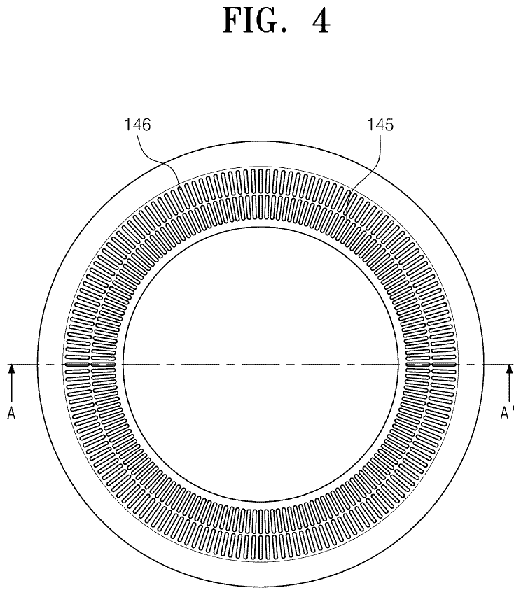

The upper space of the electrostatic chuck 130 may be a space where the plasma gas is provided for the processing of the substrate 110, and the lower space is a space where the plasma gas is discharged. Therefore, the baffle 140 may include at least one slit through which the plasma gas passes. After the processing of the substrate 110 is completed, the plasma gas may be discharged from the upper space of the electrostatic chuck 130 to the lower space through the slit. In FIGS. 1 to 3, at least one slit included in the baffle 140 is not illustrated, but the slit will be described in detail with reference to FIGS. 4 to 10.

The baffle 140 may include a body section 142 having a cylindrical shape. For example, the baffle 140 may include the body section 142 having a cylindrical shape. Furthermore, the baffle 140 may include a wing section 144 provided along the edge of the body section 142. Specifically, the wing section 144 may have a ring shape along the edge of the body section. Accordingly, the body section 142 and the wing section 144 may be provided perpendicularly.

Meanwhile, at least one slit described above may be provided in the body section 142 and/or the wing section 144 of the baffle 140. Specifically, the wing section 144 of the baffle may include a first set of slits, and the body section 142 of the baffle may include a second set of slits.

The baffle 140 may be configured to be raised or lowered. Specifically, the baffle 140 may be raised or lowered by the baffle gear 152, the second ball screw 154, and the second bellows 164.

Specifically, a first end of the second ball screw 154 may be connected to the baffle gear 152, and a second end may be connected to a motor by using a pulley and a belt. The second ball screw 154 may control the raising and lowering of the baffle 140 by transmitting power of the motor to the baffle gear 152. At this point, when the motor is provided in the plasma processing device, the plasma processing of the substrate 110 may be affected as the motor is operated, and the vacuum region may put a strain on the motor. Therefore, the motor for controlling the second bellows 164 may be provided outside the plasma processing device (specifically, a chamber) and may provide power to the second ball screw by the belt.

The baffle gear 152 may be connected to the electrostatic chuck 130 and the baffle 140. Furthermore, the baffle gear 152 may be connected to the second ball screw 154 to be provided with the power of the motor. The baffle gear 152 is rotated by the power supplied by the motor to control the movement of the electrostatic chuck 130 and the movement of the baffle 140. At this point, when the baffle gear 152 is rotated at a first angle, the electrostatic chuck 130 may move to a first height, and the baffle 140 may move to a second height. Furthermore, at this point, the second height may be higher than the first height. In other words, the distance of the baffle 140 moved by the baffle gear 152 may be greater than the distance of the electrostatic chuck 130.

Depending on the raising by the baffle gear 152, the electrostatic chuck 130 may move to a first point, the uppermost point, and the baffle 140 may move to a second point, the uppermost point. At this point, the second point may be higher than the first point.

Otherwise, an electrostatic chuck gear connected to the electrostatic chuck 130 may be provided separately from the baffle gear 152. Specifically, a first baffle gear may be connected to the baffle 140 to control the raising and lowering of the baffle 140, and the electrostatic chuck gear may be connected to the electrostatic chuck 130 to control the raising and lowering of the electrostatic chuck 130. In this case, the electrostatic chuck 130 and the baffle 140 may be independently raised or lowered. However, in this case, the uppermost raised point of the baffle 140 may also be higher than the uppermost raised point of the electrostatic chuck 130. Therefore, the body section 142 of the baffle 140 may confine the substrate 110.

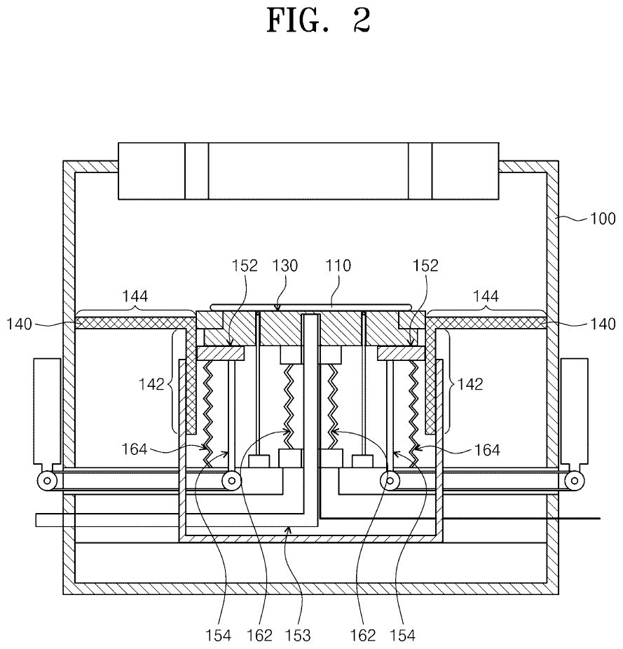

FIG. 2 is a view illustrating raising of an electrostatic chuck and raising of a baffle by a baffle gear of the present disclosure.

Referring to FIG. 2, it is shown that the electrostatic chuck 130 and the baffle 140 are raised as the baffle gear 152 is rotated by the motor. At this point, compared to FIG. 1, it is shown that the degree of raising of the baffle 140 is greater than the degree of raising of the electrostatic chuck 130.

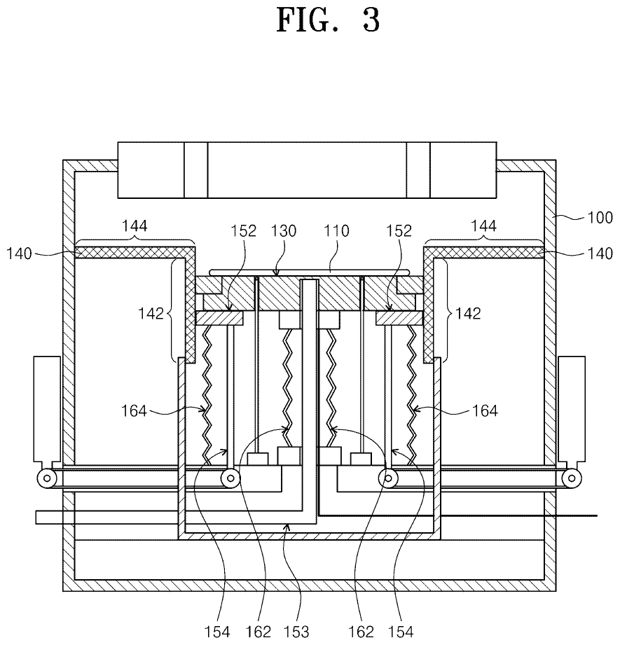

FIG. 3 is a view illustrating the electrostatic chuck and the baffle at one point according to the raising.

Referring to FIG. 3, when the baffle gear 152 is rotated at a second angle greater than the first angle, the height of the baffle 140 may be higher than the height of the electrostatic chuck 130. Eventually, when the baffle gear 152 performs as many rotations as it is preset to perform, the baffle 140 may be moved to a position confining the electrostatic chuck 130.

The body section 142 of the baffle 140 is positioned higher than the position of the substrate 110 and may serve as a wall encasing the substrate 110. In other words, the baffle 140 may allow plasma gas to be concentrated in a region where the substrate 110 is provided. Accordingly, plasma is evenly distributed on the substrate 110, and the thickness of a gas layer of the substrate 110 processed using the plasma gas may be relatively constant in every region.

Referring to FIG. 1 again, the first bellows 162 may contain the first ball screw 153 therein. Furthermore, the second bellows 164 may contain the first bellows 162 and the second ball screw 154 therein. At this point, a gap between the first bellows 162 and the second bellows 164 may be a vacuum region. Specifically, the region with the substrate 110 is a high vacuum region, and the region between the first bellows 162 and the second bellows 164 may be a sealed vacuum region. Accordingly, the sealed vacuum region may minimize a particle issue depending on the movement of the ball screws.

Hereinbelow, the baffle including at least one slit will be described in detail with reference to FIGS. 4 to 10.

FIGS. 4 to 6 are views illustrating the baffle according to an embodiment of the present disclosure.

Referring to FIG. 4, the baffle 140 may include a first set of slits. A first set of slits may be arranged in a predetermined radius from a center portion of the baffle 140. At this point, the center portion of the baffle 140 may be the origin of a circular baffle on the plan view of FIG. 4.

A first set of slits may include a first sub-set of slits 145 and a second sub-set of slits 146. The first sub-set of slits may be arranged in a first radius from the center portion of the baffle 140, and the second sub-set of slits 146 may be arranged along a second radius from the center portion of the baffle 140. At this point, the second radius may be greater than the first radius. Accordingly, based on the center portion of the baffle 140, the first sub-set of slits 145 may be arranged along the center portion, and the second sub-set of slits 146 may be arranged along outer surfaces of the first sub-set of slits 145.

The shapes of the slits included in the first sub-set of slits 145 and the shapes of the slits included in the second sub-set of slits 146 may be identical, but different from each other. Furthermore, unlike FIG. 4, to efficiently discharge plasma gas, the slits included in the first sub-set of slits 145 and the slits included in the second sub-set of slits 146 may be alternately arranged, but are not limited thereto.

FIG. 4 illustrates the shapes of a plurality of slits included in a a first set of slits as round bars, but are not limited thereto, and the slits may not have the round bar shapes and have different shapes from each other. For example, the thickness of each slit may be thick as the slit is far away from the center portion of the baffle 140. Furthermore, for example, the number of slits may be differently preset according to a position of the wing section 144.

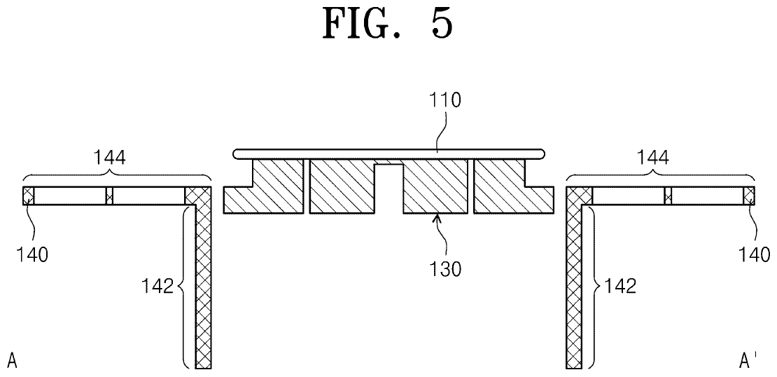

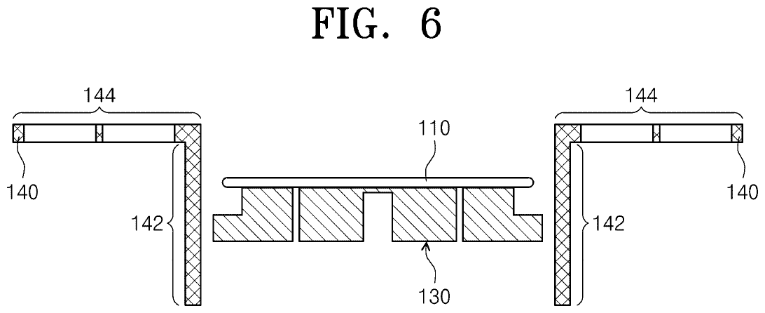

FIGS. 5 and 6 are sectional views illustrating the baffle 140 according to the embodiment.

Referring to FIG. 5, when the baffle 140 is checked in the sectional view, it is shown that at least one slit is formed on the wing section of the baffle 140.

FIG. 6 shows a section of the baffle 140 when the baffle 140 is moved to a position higher than the electrostatic chuck 130. Through at least one slit formed in the baffle 140, plasma gas of the space where the substrate 110 is positioned (upper space of the electrostatic chuck 130) may be discharged to the space where the substrate 110 is not positioned (lower space of the electrostatic chuck 130).

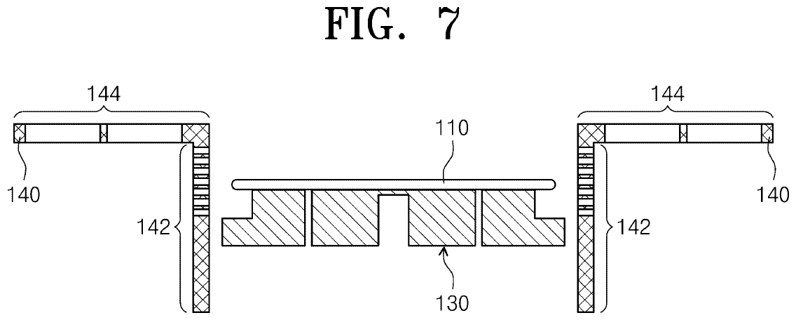

FIG. 7 is a view illustrating the baffle 140 according to another embodiment of the present disclosure.

FIG. 7 shows at least one slit (the second set of slits) also formed in the body section 142 of the baffle 140. A slit may be formed not only in the wing section 144 of the baffle 140 but also in the body section 142. At this point, the second set of slits may be preset to be positioned depending on raised positions of the electrostatic chuck 130 and the baffle 140.

When the second set of slits are preset to be also positioned below a lower end portion of the electrostatic chuck 130, the plasma gas discharged through the slits may be discharged to the space below the electrostatic chuck 130, which is a problem. Therefore, the second set of slits may be preset to be positioned between a position where the lower end portion of the electrostatic chuck 130 is positioned when the electrostatic chuck 130 is raised to the uppermost position and a position where the baffle 140 is raised to the uppermost position. Therefore, plasma gas may be discharged constantly from the space with the substrate 110 to the space without the substrate 110.

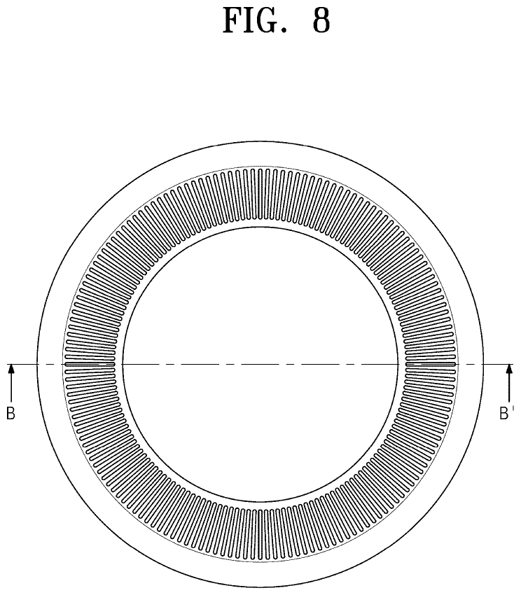

FIGS. 8 to 10 are views illustrating the baffle according to further embodiments of the present disclosure.

Referring to FIG. 8, it is shown that slits differently shaped from the slits of FIG. 4 are formed in the baffle 140. Specifically, the slits of FIG. 4 have a form in which the first sub-set of slits and the second sub-set of slits are arranged in two layers. However, the slits of FIG. 8 have a form in which the slits are not arranged in two layers but one layer. Unlike the form shown in FIG. 8, the first set of slits may be arranged to be oblique (in a comb-teeth shape) to the origin of the baffle such that one end of each slit is disposed in a direction different from a direction toward the origin of the baffle 140.

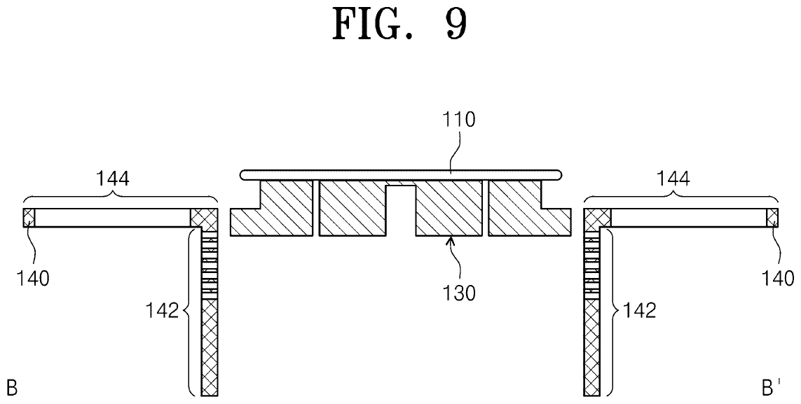

FIG. 9 illustrates a section of the baffle 140 of FIG. 8. Furthermore, the second set of slits may be formed also in the body section 142 of the baffle 140 of FIG. 9.

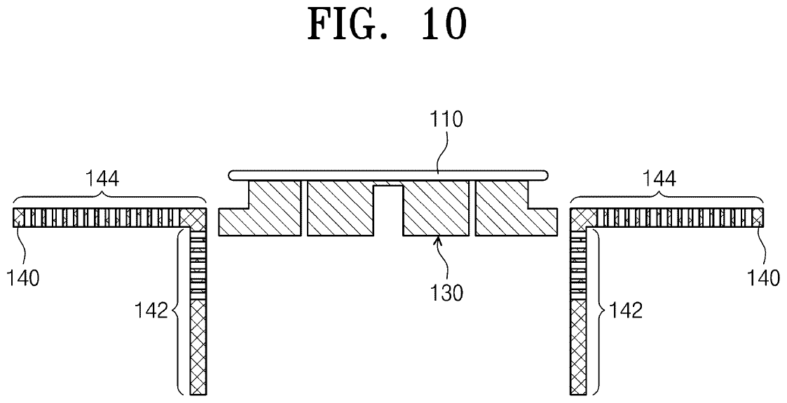

FIG. 10 illustrates slits having different shapes from the slits of FIGS. 4 to 9. The first set of slits formed in the wing section 144 of FIG. 10 may be formed in multiple layers of slits like FIG. 4 and may be formed in multiple circular shapes. Likewise, the slits formed in the body section 142 and/or the wing section 144 of the baffle 140 may have forms that is not limited to the forms described in the specification of the present disclosure and may be various.

Although the preferred embodiments have been described with the limited embodiments and drawings, those skilled in the art will appreciate that various modifications, additions and substitutions are possible. For example, even when the techniques described are performed in a different order than the described method, and/or components of the described system, structure, device, circuit, etc. are coupled or combined to each other in a form different from the described method or are replaced or substituted by other components or equivalents, appropriate results can be achieved.

Therefore, other aspects, other embodiments, and equivalents to the claims are also included within the scope of the claims.

1. A plasma processing device comprise:
an electrostatic chuck configured to support a substrate inside a chamber; and
a baffle comprising a body section having a cylindrical shape and a wing section having a ring shape along an edge of the body section,
wherein the wing section comprise a first set of slits configured to discharge at least a part of gas provided for the substrate.

2. The plasma processing device of claim 1, wherein the body section comprises a second set of slits configured to discharge at least a part of gas provided for the substrate.

3. The plasma processing device of claim 1, further comprising:
a baffle gear connected to both the electrostatic chuck and the baffle and, while being rotated at a first angle, configured to move the electrostatic chuck to a first height and to move the baffle to a second height,
wherein the second height is higher than the first height.

4. The plasma processing device of claim 3, wherein depending on the raising by the baffle gear, the electrostatic chuck is raised to a first point, and the baffle is raised to a second point, and
the second point is higher than the first point.

5. The plasma processing device of claim 3, further comprising:
a first ball screw configured to support the electrostatic chuck; and
a second ball screw configured to support the baffle gear.

6. The plasma processing device of claim 5, further comprising:
a first bellows configured to contain the first ball screw; and
a second bellows configured to contain the second ball screw,
wherein a vacuum region is provided between the first bellows and the second bellows.

7. The plasma processing device of claim 6, further comprising:
a pulley connected to the second ball screw; and
a motor connected to the pulley by a belt,
wherein to minimize a strain on the motor due to the vacuum region, the motor is located outside the chamber to provide power to the second ball screw by the belt.

8. The plasma processing device of claim 4, wherein the body section comprises a second set of slits configured to discharge at least a part of gas provided for the substrate, and
a position of the second set of slits is set between a height of a lower end of the electrostatic chuck at the first point and a height of the second point.

9. The plasma processing device of claim 1, wherein the first set of slits is arranged in a predetermined radius from a center portion of the baffle.

10. The plasma processing device of claim 9, wherein the first set of slits comprises a first sub-set of slits and a second sub-set of slits,
wherein the first sub-set of slits is disposed in a first radius from the center portion of the baffle, and
the second sub-set of slits is arranged in a second radius larger than the first radius from the center portion of the baffle.
